(19) United States
(12) Patent Application Publication
(10) Pub. No.: US 2009/0258787 A1
(43) Pub. Date: Oct. 15, 2009

(54) Superconducting Wires and Cables and Methods for Producing Superconducting Wires and Cables

(75) Inventors: Arnold E. Wilkie, Merritt Island, FL (US); Bennie F. Shuler, Indialantic, FL (US); Jeffrey S. Haggard, Cocoa, FL (US)

Correspondence Address: EDELL, SHAPIRO & FINNAN, LLC, 1901 RESEARCH BOULEVARD, SUITE 400, ROCKVILLE, MD, 20850, US

(73) Assignee: Hills, Inc., West Melbourne, FL (US)

(21) Appl. No.: 12/413,883

(22) Filed: Mar. 30, 2009

Related U.S. Application Data
(60) Provisional application No. 61/040,675, filed on Mar. 30, 2008.

(51) Int. Cl. H01B 12/02; H01L 39/24; H01L 39/00

(52) U.S. Cl. 505/231; 505/434; 505/433; 505/150; 427/62; 174/125.1

(57) ABSTRACT

A superconductor structure is manufactured by forming a channel within a substrate along a surface of the substrate, depositing a material within the channel of the substrate, where the material includes one of a superconductor material and a precursor for a superconductor material, and thermally treating the substance within the channel of the substrate so as to form an elongated superconductor wire formed as a single, cohesive structure. The substrate can further include a plurality of channels with superconductor wires formed within the channels. In addition, a cable is formed including a bundle of individual superconductor wires arranged at different spatial positions with respect to each other.

### CROSS REFERENCE TO RELATED APPLICATION

This application claims priority from U.S. Provisional Patent Application Ser. No. 61/040,675, entitled “Method of Manufacturing Superconducting Wire and Cable”, and filed Mar. 30, 2008, the disclosure of which is incorporated herein by reference in its entirety.

### FIELD OF THE INVENTION

The present invention pertains to methods for producing superconducting wires and cables, and also products associated with such methods.

### BACKGROUND

Superconductivity is a property of certain metals, alloys and other materials to become electrically conductive with little or no electrical resistance and also diamagnetic at temperatures approaching absolute zero. In order for a material to become superconductive the material must be cooled below a superconducting transition or critical temperature for the material, and this critical temperature differs for different materials. Elemental mercury was one of the first materials found to exhibit superconductivity at a temperature of about four degrees absolute or Kelvin (4 K). Superconductivity has also been found to occur in a wide variety of other materials, including lead, tin and aluminum, various metallic alloys and some heavily-doped semiconductor materials. Other types of materials, referred to as high temperature superconductivity ceramic materials (e.g., bismuth strontium calcium copper oxide (BSCCO) and yttrium barium copper oxide (YBCO)), have also been determined to have superconducting properties at temperatures above about 30 K.

In recent years, magnesium diboride (MgB₂) has been determined to exhibit superconducting properties at temperatures of about 39 K. Magnesium diboride has become popular in the focus for the use of superconductor materials because it is relatively inexpensive and easy to synthesize by high temperature reaction between boron and magnesium powders at temperatures of about 650° C. or greater.

Superconducting magnesium diboride wires can be produced using a powder-in-tube process in which a mixture of boron and magnesium powder is poured into a metal tube (or a partially formed and open tube which is then closed after filling with the powder) and the tube is subsequently reduced in diameter by conventional wire drawing techniques. The tube is then heated to the reaction temperature to form MgB₂ within the tube. Alternatively, the tube can be filled with MgB₂ powder, reduced in diameter by a drawing process, and then sintered at elevated temperatures. The drawn tube with MgB₂ forms a wire of a selected diameter. A number of such MgB₂ wires can be fit within a larger diameter tube to form a cable containing a bundle of wires extending in the same general longitudinal direction, thus providing small filaments of the superconducting MgB₂ extending through the cable. An example of forming superconducting fibers and cables including such fibers is described in U.S. Pat. No. 6,687,975.

The powder-in-tube process for forming a cable including a bundle of superconducting wires is cumbersome and expensive. In addition, since MgB₂ is a fairly brittle material, it is very difficult to draw individual wires sufficiently to achieve the desired diameters for such wires.

It is therefore desirable to provide an improved process for forming superconducting wires and also cables including bundles of such superconducting wires.

### SUMMARY OF THE INVENTION

According to the present invention, a method of forming a superconductor structure comprises forming a channel within a substrate along a surface of the substrate, depositing a material within the channel of the substrate, where the material comprises one of a superconductor material and a precursor for a superconductor material, and thermally treating the substance within the channel of the substrate so as to form an elongated superconductor wire comprising a single, cohesive structure.

In accordance with another embodiment of the invention, a superconductor structure comprises a substrate including a channel formed within and along a surface of the substrate, and an elongated superconductor wire disposed within the channel of the substrate, where the superconductor wire comprises a superconductor material formed as a single and cohesive structure within the channel.

The substrate can further be formed with a plurality of channels each including a superconductor wire formed from a superconductor material. In one embodiment, the superconductor wire comprises magnesium diboride.

A cable is also formed in accordance with the present invention including a bundle of individual superconductor wires arranged at different spatial positions with respect to each other. In one embodiment, a cable is formed by winding the substrate including a plurality of channels around an elongated core such that individual superconductor wires disposed within the channels of the substrate are rotationally and radially separated from each other and extend in a longitudinal direction of the elongated core. In another embodiment, a superconductor cable can be formed by rolling or winding the substrate upon itself instead of being wound around a core. In yet another embodiment, a plurality of substrates including channels with superconductor wires disposed therein are stacked upon each other.

The present invention provides easy and efficient methods for simultaneously forming a plurality of superconductor wires and also bundles of wires for superconductor cables.

The above and still further features and advantages of the present invention will become apparent upon consideration of the following definitions, descriptions and descriptive figures of specific embodiments thereof wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

FIGS. 1-6 are cross-sectional views taken along a transverse dimension of a substrate and show a series of processing steps in accordance with one embodiment of the invention, where the substrate is modified to include channels with superconducting material provided or formed within the channels to form superconductor wires within the channels.

FIG. 7 is a cross-sectional view of a superconducting cable formed in accordance with an embodiment of the invention.

FIG. 8 depicts a process step in which the superconducting cable of FIG. 7 is drawn along its longitudinal dimension.

FIG. 9 is a cross-sectional view along a dimension of a two-layered substrate including channels in the two layers that face and combine with each other to form a series of superconducting wires in the channels in accordance with another embodiment of the invention.

FIG. 10 is a cross-sectional view of a superconducting cable formed in accordance with the invention utilizing the substrate of FIG. 9.

FIG. 11 is a cross-sectional view along a transverse dimension of stacked substrates that are used to form superconducting wires in channels that extend through one of the substrates in accordance with a further embodiment of the invention.

FIG. 12 is a top view in plan of a substrate formed in accordance with the invention in which a series of channels extend along the longitudinal dimension of the substrate and are filled with superconducting material.

FIG. 13 is a cross-sectional view taken along a transverse dimension of a series of substrates including channels with superconducting material, where the substrates are in a stacked arrangement.

FIG. 14 is a side view in elevation of a cable including a plurality of superconductor wires formed in a helical manner around an elongated core in accordance with an embodiment of the invention.

FIG. 15 is a top view in plan of a substrate formed in accordance with the invention in which a series of different shaped channels extend along the longitudinal dimension of the substrate and are filled with superconducting material.

### DESCRIPTION OF THE PREFERRED EMBODIMENTS

In accordance with the invention, superconducting wires (also referred to as superconductor wires) and also cables including bundles of superconducting wires are formed in a more efficient and less cumbersome and time consuming manner in relation to conventional methods for forming such wires and cables. In particular, a unique approach is described herein for forming superconducting wires and cables that is significantly different from the conventional powder-in-tube approach in which superconducting powder is inserted within a tube and processed to form the superconducting wire. A series of grooves or channels are formed within a substrate in the form of a thin sheet, plate or foil, and the grooves are filled with superconducting material (or precursor material that can be subsequently processed within the grooves to form superconducting material), where the sheet is then processed to form individual superconducting wires. In one embodiment, described in further detail below, the channels are formed along a longitudinal (i.e., lengthwise) dimension of the sheet, and the sheet is then folded or rolled over upon itself in a transverse direction (e.g., along its width) in a spiraling manner so as to form a superconducting cable in which a plurality of separate and individual superconducting wires or filaments extend longitudinally through the cable and are spaced from each other in both radial and angular directions.

Any suitable superconducting material can be provided within the channels of the base substrate. Alternatively, any one or more precursor materials can be provided within the channels of the base substrate, where the precursor materials are further processed within the channels to form the superconducting material. The term “superconducting material”, as used herein, refers to any material that exhibits a reduction in electrical resistance (e.g., exhibits zero resistance or very near zero resistance) and/or becomes diamagnetic at temperatures approaching absolute zero (e.g., temperatures below about 150 K). Any suitable superconducting material can be used to form the wires and cable of the present invention. Non-limiting examples of both low temperature and high temperature superconductor materials that can be used to form superconducting wires and cables in accordance with the invention include the following compounds: yttrium barium copper oxide (e.g., YBa₂Cu₃O₇), bismuth strontium calcium copper oxide (e.g., Bi₂Sr₂CaCu₂O₈ or Bi₂Sr₂Ca₂Cu₃O₁₀), mercury barium calcium copper oxide (e.g., HgBa₂Ca₂Cu₃O₉), thallium barium calcium copper oxide (e.g., TlBaCaCuO), molybdenum sulfides (e.g., Mo₆S₈, LaMo₆S, LaMo₆S₈, Cu₂Mo₆S₈, Yb_{1.2}Mo₆S₆, Pb_{0.9}Mo₆S_{7.5}, PbMo₆S₈, HoMo₆S₈, and BrMo₆S₈), YPd₂B₂C, ErRh₄B₄, Sr₂RuO₄, MoC, NbC, NbN, NbTi, Nb₃Sn, Nb₃Ge, ZrN, V₃Si, CaRh₂, CaIr₂, ZrV₃, HfV₂, and MgB₂. In one example, a superconductor material can be applied to the channels of the substrate in particulate or powder form and then further processed (e.g., via sintering or any other chemical and/or heat treatment) to adhere or fuse the particles together so as to form a single, cohesive and unitary superconductor material in the form of a filament or wire within each channel. Magnesium diboride (MgB₂) is one such material that can be applied as MgB₂ powder or, alternatively, as magnesium and boron powders which, upon heat treatment at about 650° C. or greater, results in the formation of MgB₂. However, it is noted that superconductor materials can be deposited in any suitable form or forms (e.g., by solid, liquid and/or vapor deposition) within the channels. For example, in certain embodiments, a superconductor material can be deposited in the form of a slurry or as a paste within the channels of a substrate.

A doping material can also be combined in any suitable amount with the superconductor material to enhance the physical properties and electrical performance of the material. An example of a suitable doping material for MgB₂ is silicon carbide (SiC).

The substrate for forming channels can comprise any one or combination of suitable materials. For example, the substrate material can be formed from metals including, without limitation, copper, silver, gold, platinum, palladium, aluminum, iron, nickel, chromium magnesium, titanium, molybdenum, tungsten, lead and any combination thereof, including alloys that can be formed with such metals (e.g., iron alloys such as stainless steel).

Additionally, depending upon the type of metal substrate used, it may be desirable to provide a coating over at least one surface of the substrate, or at least over surface portions including the channels, to prevent direct contact and potential chemical reactions between the superconducting material and the substrate. In particular, undesired chemical reactions (e.g., oxidation reactions) may occur between copper substrate surfaces and MgB₂ or other superconducting materials during thermal treatment of the material within the substrate channels. To prevent such reactions, a coating of another material that is relatively inert or non-reactive with respect to MgB₂ and copper can be provided over the substrate surface. For example, a coating of boron can be vapor deposited over the substrate surface including the channels (e.g., via a chemical or physical vapor deposition process) prior to deposition of the powder material forming the superconducting material within the channels. Alternatively, the surface of the copper substrate including the channels can be coated with another metal material, such as nickel, iron, a nickel alloy or an iron alloy (e.g., stainless steel), all of which are non-reactive with MgB₂, so as to protect the copper surface from reaction with MgB₂.

An example process for forming superconducting filaments or wires within a substrate is described with respect to FIGS. 1-6. In this example process, MgB₂ is the superconducting material formed within channels of the substrate. However, it is noted that any other superconducting material (or precursor materials for forming a superconductor material) can also be used to form the wires within the substrate channels. The substrate comprises a stainless steel sheet. However, as noted above, the substrate can also be formed from any other suitable material, such as any of the materials described above.

Referring to FIG. 1, a stainless steel base sheet 2 is provided having a suitable thickness (t). The sheet thickness (t) can be of any suitable dimension that facilitates the formation of grooves or channels of suitable dimensions within the sheet and which further facilitates manipulation of the sheet such as folding of the sheet or separation of the sheet into multiple sections in process steps as described below. The sheet can be a thin plate or foil having a thickness between about 25 micrometers (microns) to about 1,000 microns. The sheet can have a specified longitudinal dimension or, alternatively, can be a continuous sheet that is wound longitudinally from one reel and transported for winding onto another reel, with processing of the continuous sheet occurring between the two reels.

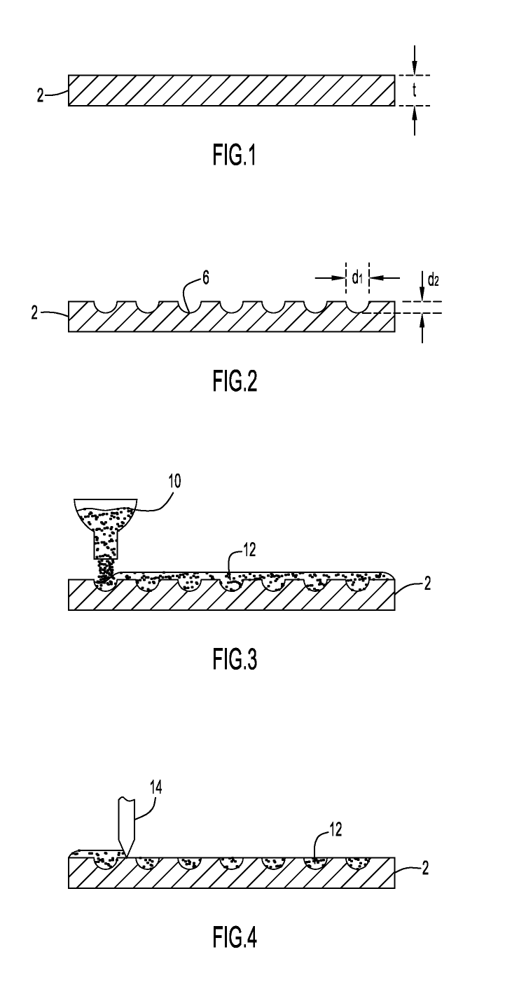

Grooves or channels 6 are formed within a surface of the sheet 2 as shown in FIG. 2, where the depth (d₂) of the channels 6 is less than the thickness (t) of the sheet 2. The channels 6 are formed as generally or substantially linear channels extending in a direction that is generally or substantially parallel with the longitudinal dimension of the sheet, and the channels are transversely spaced a suitable distance from each other along the width of the sheet. However, it is noted that channels can also be formed having non-linear configurations including, without limitation, curved configurations, zig-zag configurations, sinusoidal configurations, etc. Alternatively, channels can be formed that are generally or substantially linear and that extend in a direction that is transverse the longitudinal dimension of the sheet (e.g., linear channels that are aligned in a diagonal pattern or are perpendicular in relation to the longitudinal dimension of the sheet). Any suitable technique can be used to form the channels within the surface of the sheet including, without limitation, chemical etching, electrical discharge machining, laser machining or etching, milling, rolling and stenciling. For example, for a continuous sheet, any conventional or other suitable reel-to-reel etching process can be used to provide longitudinally aligned channels within a surface of the sheet.

Each channel can be spaced from one or more other neighboring channels at any one or more suitable distances, where such distances can be chosen based upon the dimensions of the wires to be formed and also the cable to be formed with such wires. In addition, channels can be formed having any suitable width (d₁) and depth (d₂) dimensions, where the channel dimensions are chosen based upon the desired dimensions of the superconductor wires to be formed within the channels. For example, the width (d₁) of each channel can be from about 20 microns to about 5,000 microns, and the depth (d₂) of each channel can also be from about 20 microns to about 5,000 microns. While the channels 6 formed within the surface of sheet 2 have a concave and generally semi-circular cross-section, the channels can also be formed to have any other suitable cross-sectional geometric configurations including, without limitation, V-shaped and multi-faceted (e.g., square, rectangular or polygonal shaped) configurations. In addition, each channel can be formed so as to have at least one of a changing or varying width, a changing depth and a changing cross-sectional dimension along the channel.

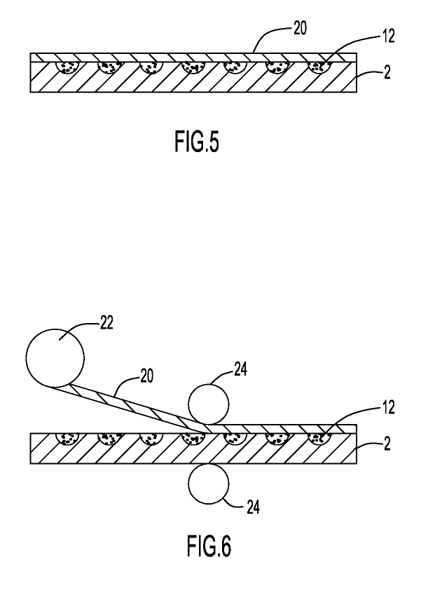

Magnesium and boron powder are provided in any suitable manner within the formed channels of the substrate. For example, referring to FIGS. 3 and 4, a powder mixture 12 comprising magnesium and boron (and, optionally a doping material such as SiC) is deposited via a tube or funnel 10 onto the surface and into the channels 6 of sheet 2, and the excess powder 12 is then wiped from the surface with a wiping blade 14 such that the powder 12 remains within channels 6 but is substantially removed from other surface portions of the sheet 2. Alternatively, powder can be deposited directly into individual channels 6 while substantially avoiding deposition along other surface portions of the sheet. While this example depicts magnesium and boron being deposited in the form of powder or particulate material within the channels, as noted above, superconducting materials can also be deposited in any other form (e.g., solid, liquid and/or vapor deposition) within the channels of the sheet.

The powder 12 can be compressed and compacted into the channels 6 by rolling the sheet between two compression rollers and/or using any other suitable compaction equipment and compression/compaction techniques. Compression of the powder within the channels is preferably carried out in a vacuum so as to remove any air and potential voids within the powder or between the powder and sheet surface sections within the channels. After compression, any excess powder forced from the channels can be removed from the substrate surface (e.g., using a wiping blade 14 such as is shown in FIG. 4).

As shown in FIG. 5, a second sheet 20 is placed over the surface of the sheet 2 including the channels 6 filled with powder 12 so as to enclose the filled channels between the adjacent surfaces of the two sheets. The second sheet can be formed of any suitable material including, without limitation, any of the materials described above for the first sheet. As shown in FIG. 5, the second sheet 20 does not include any grooves or channels on its engaging surface, but instead includes a substantially flat surface that engages the channeled surface of sheet 2 to enclose the grooves. The two sheets can optionally include any suitable adhesive or other bonding materials to enhance bonding of the two sheets together and enclosing of the channels between the two sheets. When sheet 2 is a continuous sheet being unrolled from a reel, sheet 20 can be applied to sheet 2 as shown in FIG. 6, in which sheet 20 is rolled from reel 22 and engages sheet 2 between two compaction rollers 24.

The combined sheet structure of FIG. 5 (with magnesium/boron powder sealed within the channels between the sheets) is subjected to heat treatment (e.g., within one or more ovens or furnaces) at a suitable temperature (e.g, about 650° C. or greater) and for a suitable time period to facilitate a chemical reaction as well as sintering so as to form a MgB₂ superconducting material having a single or unitary and cohesive filament or wire structure within each channel 6 of sheet 2. The heating process is preferably carried out under suitable pressure to prevent and/or eliminate the formation of voids within the superconducting material formed during the reaction/heating process. Additionally, the heating process is of sufficient temperature and duration to facilitate bonding or brazing between the two sheets 2 and 20 so as to form an integral or fused structure from the two joined sheets. The two sheets can also be joined together using any other suitable methods.

As an alternative to providing a mixture of magnesium and boron powder, a MgB₂ superconducting material can be directly deposited within the channels of the first sheet. In this embodiment, a heating step is provided to sinter the MgB₂ powder to form the unitary and cohesive filament or wire structure within each channel of the sheet.

The combined sheets containing the superconducting MgB₂ wires can be further processed to form cables including a plurality or bundle of the superconducting wires. In one example shown in FIG. 7, a cable 30 is formed by folding or rolling the combined sheets 2 and 20 upon themselves in a transverse direction of the sheets (i.e., along the width of the sheets) and around an elongated core or rod 26. In particular, sheets 2 and 20 are oriented such that the longitudinal dimensions of the sheets are aligned with the longitudinal axis of rod 26, with a longitudinal edge of the surface portion of sheet 2 opposite the channeled surface being placed upon the rod 26. The joined sheets 2 and 20 are then rolled up or wound around rod 26 such that the sheets form a continuous outward spiral from the centrally located rod 26. In this rolling process the surface portions of sheet 2 may engage surface portions of sheet 20 as the sheets are spirally wound and extend in an increasing radial direction from rod 26 until the outward spiral terminates at the second longitudinal edge of sheet 2. Superconductor wires comprising MgB₂, which are formed within channels of sheet 2, are oriented substantially parallel to the longitudinal axis of cable 30 and are arranged at radial and angularly spaced locations (i.e., individual longitudinally extending wires that are separate from each other) throughout the thickness of the cable. The superconducting wires 13 extend in a generally or substantially linear direction through the cable and further in a direction that is generally or substantially parallel with the longitudinal axis of the cable. However, as noted below, the winding of the sheets 2 and 20 around rod 26 and/or the formation of the superconducting wires 13 within sheet 2 can be modified such that the wires 13 can extend in a variety of different non-linear pathways between the opposing longitudinal ends of the rod 26.

Any suitable adhesive can be applied to an exposed surface of either or both of sheet 2 and sheet 20 to facilitate adhesion between adjacent surface portions of the continuous spiral formed around the rod 26. Alternatively, the formed cable 30 can be subjected to stapling, welding and/or further heat treatment to facilitate bonding between the adjacent surface portions of sheets 2 and 20 of the continuous spiral so as to ensure the cable is formed as a unitary, integral and cohesive unit.

The rod 26 can be any suitable material including, without limitation, any of the materials described above for the substrate. In addition, the rod 26 can have a circular cross-sectional shape (as shown in FIG. 7) or, alternatively, any other suitable cross-sectional shape (e.g., triangular, elliptical, multi-faceted such as square or rectangular shaped, irregular shaped, etc.). The rod provides a rigid core for structural support of the cable and can further be designed with any number of bends or curves along its longitudinal dimension to achieve a desired curved or bent structural configuration for the cable. It is further noted that the centrally located rod can form part of the cable (as shown in the embodiment of FIG. 7) or, alternatively, the rod can be removed from the spirally wound sheet structure and the superconductor wires such that the resultant cable has a longitudinally extending open or hollow section at its center.

The rod 26 can also be formed of an electrically conductive material such as copper, such that the cable 30 assembly includes both superconductor wires 13 extending through the cable and another electrical conductor in the form of rod 26 that also extends through the cable and provides another electrically conductive pathway when the superconductor material is not in an electrically conductive state (during periods when the superconductor material becomes non-superconductive). For this purpose rod 26 may be a solid member or an assembly of tightly braided copper or other electrically conductive wires. Alternatively, as noted above, one or both of sheets 2 and 20 can also be formed of an electrically conductive material to provide an alternative electrical pathway for the cable 30 in addition to the superconductor wire pathways through the cable.

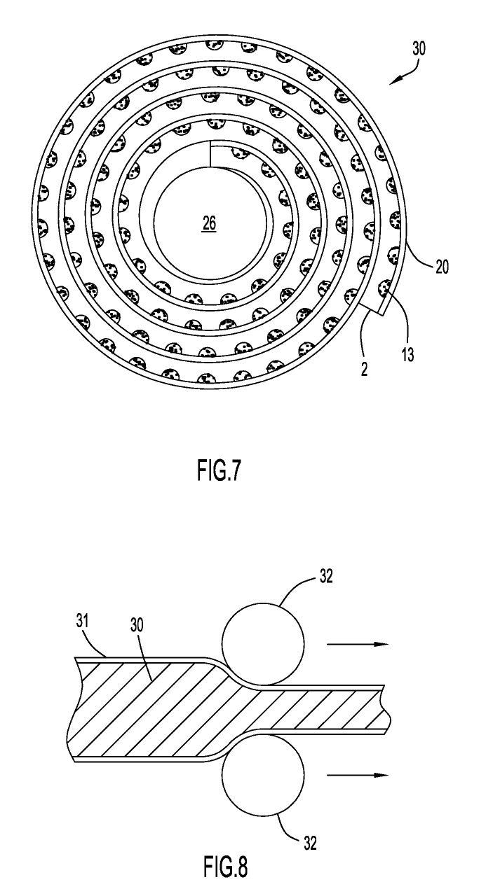

Cable 30 can be further processed in any suitable manner to achieve desired length and/or cross-sectional dimensions of the cable. For example, cable 30 can be placed within a sheath 31 formed of a metal such as copper and then subjected to a drawing process such as is shown in FIG. 8, in which the cable is drawn along its longitudinal dimension between two compaction rollers 32 so as to elongate the cable and reduce its cross-sectional dimension. The cable 30 can also be drawn or processed in any other manner without the use of the sheath. For this drawing process, the powder material 12 within substrate channels 6 is preferably not processed or thermally treated to form the superconductor material 13 until after the drawing process. Elongation of the cable in this manner can further modify the dimensions of the superconductor wires within the cable (e.g., reducing the transverse dimensions and elongating the longitudinal dimensions of the wires).

In a modification to the embodiment described above and depicted in FIGS. 1-7, it is noted that the second sheet can be eliminated for certain embodiments, where the channels of the first sheet are not enclosed by the second sheet but instead the first sheet is folded or rolled/wrapped over upon itself and around the elongated core or rod in a spiral configuration to form the cable. In addition, the first sheet with channels including the superconductor material (or precursor material that forms the superconductor material) can be subjected to elongation by drawing the sheet along its longitudinal dimension so as to reduce the thickness of the grooves (which reduces the thickness of the wires formed) and also to further eliminate any voids within the powder.

It is further noted that a cable similar to cable 30 shown in FIG. 7 can also be formed without the use of an elongated core. In such embodiments, the sheet including the channels filled with material can be folded or rolled upon itself (e.g., starting at one longitudinal edge of the sheet and rolling the sheet from this edge upon itself toward the opposing longitudinal edge of the sheet). The folded or rolled up sheet forms an elongated cable including superconductor wires extending between the longitudinal ends of the cable and separated from each other in both angular and radial directions with respect to the central axis of the cable. In these embodiments, the sheet can also be folded in any suitable manner so as to form a cable having a variety of different cross-sectional shapes including, without limitation, circular, triangular or polygonal. In addition, the sheet can be folded in alternating patterns so as to form an undulating or accordion-shaped pattern taken along a cross-section of the folded sheet.

As noted above, the channels defined within the first sheet can be formed with any suitable cross-sectional geometries so as to facilitate forming superconducting wires with complementary cross-sectional shapes. In the embodiment of FIG. 7, the superconducting wires 13 have a generally semicircular cross-sectional shape resulting from the shape of the channels within which the wires were formed.

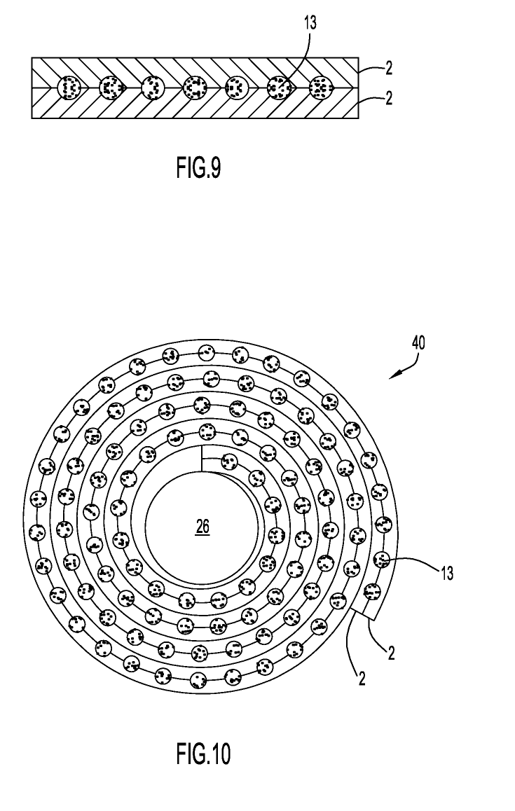

In another embodiment, wires 13 can be formed having generally circular cross-sectional shapes as shown in FIGS. 9 and 10. This is accomplished by folding sheet 2 over upon itself along its transverse dimension, after the processing step shown in FIG. 4, such that channels 6 face and are aligned with each other upon pressing the folded surface portions of sheet 2 against each other. The semi-circular shaped channels 6 aligned with other semi-circular shaped channels 6 define resultant channels that are circular in cross-section and contain compacted powder. The folded over sheet 2 can then be subjected to heat to form the unitary and cohesive superconductor wire structure 13 in each channel which has a generally circular cross-section and cylindrical shape. In this embodiment, a second sheet is not required, since the folding over of the second sheet upon itself serves to enclose the channels. The folded over sheet 2 shown in FIG. 9 is then wound up upon a core 26 to form a cable 40 in the same manner in which cable 30 is formed (as described above). As an alternative to folding sheet 2 upon itself in the embodiment shown in FIGS. 9 and 10, a second sheet having similar channel dimensions and channel shapes can be applied to sheet 2 such that channels for both sheets face and are aligned with each other when the two sheets are pressed together, which results in the formation of superconductor wires having shapes complementary to the combined channel shapes of the first and second sheets.

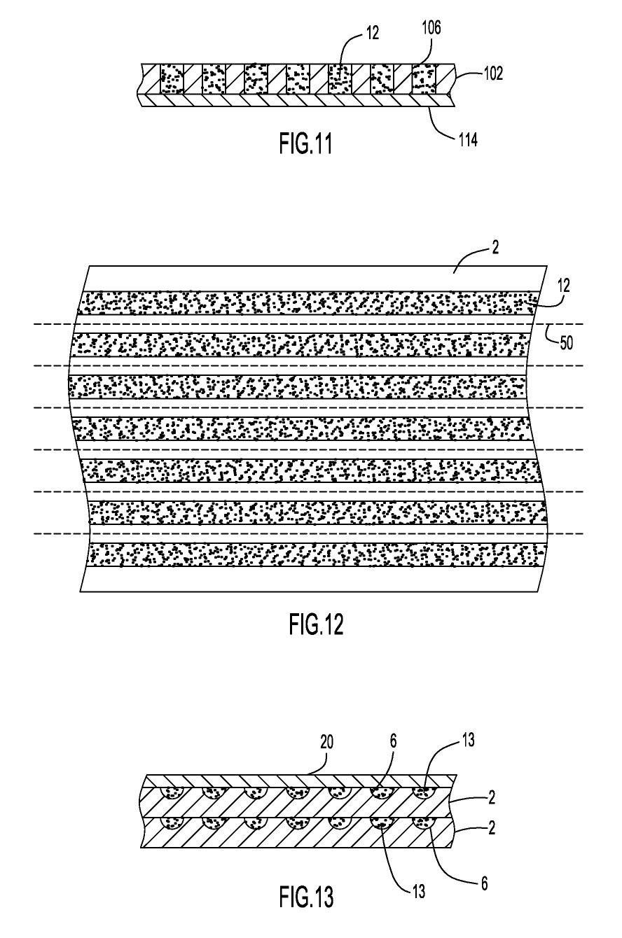

In another embodiment shown in FIG. 11, a sheet 102 can be formed with channels 106 that extend completely through the channeled sheet. The channels can be formed using any etching, milling or other suitable technique. A lower or base sheet 114 is adhered and/or brazed or bonded to a lower surface of sheet 102 to enclose the channels 106 along one surface of sheet 102 in order to facilitate deposition of powder 12 within the channels. The sheets 102 and 114 can be formed of any suitable substrate material, such as the substrate materials described above. In addition, the powder can comprise a superconducting powder or one or more precursor materials that form a superconducting material. Superconductor wires and cables can be formed using the sheet arrangement shown in FIG. 11 in a similar manner to that described above and depicted in FIGS. 1-6, where a further sheet can be applied to sheet 102 to enclose the channels 106 after filling with powder 12 and further processing carried out to form a cable similar to that depicted in FIG. 7.

In another embodiment, the sheet structure formed in FIG. 4 or FIG. 5 can be divided, separated or singulated between channels so as to form individual superconductor wires defined and/or encapsulated within the channels of the sheet. As shown in FIG. 12, sheet 2 (which can also include sheet 20 adhered, brazed or bonded to it to enclose the channels) can be divided along cut lines 50 that extend in the same longitudinal direction as the channels but do not traverse the channels so as to form individual and separate superconducting wire structures. The sheet 2 can be separated into any number of sections that include one, two or more superconductor wires within the channels.

In a further embodiment shown in FIG. 13, a series of sheets 2 including superconductor material 13 disposed within channels 6 that extend in a longitudinal direction along surfaces of the sheets can be stacked in a vertical arrangement upon each other and bonded together so as to form a cable structure including bundles of superconductor wires. Any selected number of sheets 2 including channels 6 filled with superconductor material 13 (e.g., two sheets, three sheets, or more) can be stacked upon each other. The top sheet can optionally be enclosed with a sheet 20. The channels of the sheets can be arranged with the same or similar spacing between each other so as to form a grid including aligned horizontal rows and aligned vertical columns of superconducting wires having the same or similar cross-sectional shapes. Alternatively, the channels of the sheets can be arranged with different spacing and/or different cross-sectional shapes to provide a staggered or any other selected configuration and spacing between superconducting wires within the same sheet and/or between different stacked sheets.

As noted above, the channels formed within the substrate and which are used to form the superconducting wires of the present invention can be linear channels or, alternatively, channels having any other non-linear configuration (e.g., curved channels, sinusoidal channels, zig-zag channels, channels forming any closed or open geometric shapes or patterns, etc.). Providing non-linear channels and resultant non-linear superconductor wires within the channels can result in the formation of many different and unique cable configurations in which the substrate is coiled or wound around an elongated core (or the substrate is folded or rolled upon itself, where the elongated core is not present in the cable) and the superconducting wires formed within the substrate channels extend both in a longitudinal direction of the elongated core and also in a variety of different spatial directions between the opposing longitudinal ends of the core. For example, a substrate can be provided with one or more curved channels that form one or more curved superconducting wires within the substrate such that, when the substrate is wound or coiled around an elongated core to form a cable, the one or more curved wires extend in a helical pattern around the elongated core between opposing longitudinal ends of the core. The wires can be formed with suitable curves within the substrate such that, upon winding the substrate around the core, a double helix or even multiple helixes of superconductor wires are formed around the core.

It is noted that such non-linear (e.g., helical or coiled) patterns of superconductor wires formed around an elongated core can also be achieved using a substrate including generally linear shaped superconductor wires formed within the substrate. In such an embodiment, a slight twist can be applied to the substrate as it is wound or coiled around the elongated core between its longitudinal edges so as to result in one or more superconductor wires extending in a non-linear direction between the two longitudinal ends of the coil. The substrate can also be wound or coiled around the elongated core between the edges located at its longitudinal ends, where the substrate is further twisted slightly as it is wound around the elongated core so as to only partially cover or wrap over itself while advancing longitudinally along the surface of the core. This also results in one or more superconductor wires that extend in a non-linear manner between opposing longitudinal ends of the elongated core.

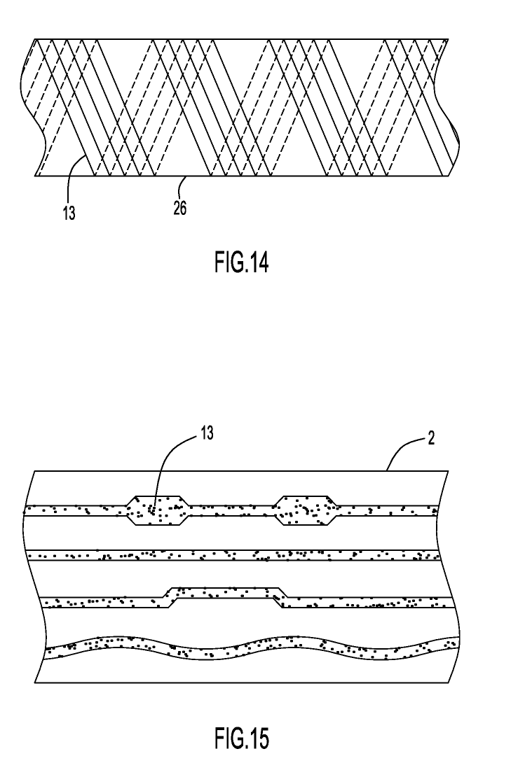

A cable including a helical configuration of superconductor wires 13 extending around the elongated core 26 is depicted in FIG. 14. As noted above, a number of different substrate and channel configurations can be provided, along with different ways in which the substrate is wrapped or wound around the elongated core, to achieve a helical winding of superconductor wires around the core. For ease of illustration, the substrate has not been shown in FIG. 14. However, it is to be understood that the wires 13 are formed in substrate 2 which is wound or wrapped around core 26 for the cable of FIG. 14.

The present invention is not limited to the embodiments described above but can be implemented in any embodiment in which superconducting wires are formed by deposition of superconducting material within channels of a substrate.

The process techniques described above result in the formation of superconducting wires that can have a wide variety of cross-sectional and longitudinal dimensions and also a wide variety of different cross-sectional shapes, since such dimensions and shapes can be achieved with relative ease by choosing appropriate channel dimensions and cross-sectional geometries within the substrates or sheets within which the superconducting wires are formed. In particular, superconducting wires can be formed in accordance with the present invention having cross-sectional dimensions that are as small as about 5 microns and even smaller.

The longitudinal dimensions of the superconductor wires and cables formed with such wires can be easily set by providing a channeled substrate of virtually any length (e.g., using a continuous sheet roll and a continuous etching or other channel forming process to form channels within the sheet roll). Thus, compaction or drawing of the superconductor wires after they are formed (which is typically required for other superconductor wire formation processes such as powder-in-tube processes) can be eliminated. The process of forming the superconductor wires and cables including bundles of superconductor wires is very simple and cost efficient using the present invention, where a plurality of separate and individual superconductor wires can be simultaneously formed and combined to form a cable using a single substrate. This is a significant improvement over powder-in-tube and other conventional methods for forming superconductor wires and bundles of such wires.

In addition, the channel dimensions, including channel width, channel depth, and channel geometry, can change for one or more channels as the channels extend across the substrate, so as to form one or more superconductor wires having different widths, thicknesses and/or different cross-sectional shapes at different locations along the lengths of wires. The spacing between two or more channels can also be modified at different locations along the substrate so that, for example, two or more superconductor wires formed in the substrate can be closer to each other at one location and farther apart at another location along the substrate. The changing of channel dimensions and/or spacing can therefore result in embodiments such as cables formed by substrates wound around elongated cores (or a substrate rolled upon itself) in which two or more superconductor wires are spaced closer to each other at one location (e.g., at or near a central longitudinal location along the cable) and spaced farther from each other at another location (e.g., at the longitudinal ends of the cable). As also noted above, the channels and resultant superconductor wires formed in the substrate can be linear or non-linear and formed in any one or more different directions along the substrate to facilitate the formation of superconductor wires and cables having a variety of different configurations. Some non-limiting examples of different shaped channels on substrate 2 including superconductor material 13 are depicted in FIG. 15. These non-limiting examples show just a few of the many different ways in which different superconductor wire sizes, spacings and orientations with respect to each other in a substrate and within a cable formed with such substrate can be modified in a relatively easy manner using the concepts of the invention and in contrast to powder-in-tube and other conventional methods for forming superconductor wiring structures.

As noted above, any suitable superconducting materials, or precursor materials forming superconductor materials, can be provided in the substrate channels. In one embodiment, the materials can be deposited in powder form and then be processed within the substrate channels to form superconductor wires where each wire has a single, unitary and cohesive structure. As noted above, superconducting materials can also be deposited in any other form and manner within the substrate channels. The substrate can also be formed of any suitable material that facilitates the formation of channels having the desired dimensions and further facilitates processing of the filled channels to form the superconductor wires. Superconductor cables can also be formed including any selected number of superconductor wires, where the superconductor cables can have configurations such as those described in the previous embodiments or any other suitable configurations in which two or more superconductor wires can be combined to form a cable structure.

Having described preferred embodiments of new and improved superconducting fibers and cables and methods for forming superconducting fibers and cables, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

What is claimed:

1. A method of forming a superconductor structure, the method comprising:
forming a channel within a substrate along a surface of the substrate;
depositing a material within the channel of the substrate, wherein the material comprises one of a superconductor material and a precursor for a superconductor material; and
thermally treating the substance within the channel of the substrate so as to form an elongated superconductor wire comprising a single, cohesive structure.

2. The method of claim 1, wherein the material is deposited as a powder.

3. The method of claim 2, wherein the superconductor wire comprises magnesium diboride.

4. The method of claim 2, wherein the material comprises magnesium powder combined with boron powder, and the substance is thermally treated within the channel to form the superconductor wire comprising magnesium diboride.

5. The method of claim 1, wherein a plurality of channels are formed within the substrate, the material is deposited within the plurality of channels and thermally treated to form a plurality of elongated superconductor wires, each superconductor wire comprising a single, cohesive structure.

6. The method of claim 5, further comprising:
securing a second substrate to the surface of the substrate including the channels so as to enclose the channels between the substrates.

7. The method of claim 6, wherein the second substrate includes a plurality of second channels formed within and along a surface of the second substrate in which the material has been deposited and thermally treated to form superconductor wires, each superconductor wire in a second channel comprising a single, cohesive structure.

8. The method of claim 7, wherein the second substrate is secured to the substrate such that the surface including the second channels of the second substrate engages the surface including the channels of the first substrate, and at least one second channel of the second substrate is aligned to combine with a channel of the first substrate so as to form a single and cohesive superconductor wire from material disposed within the combined channels of the substrates.

9. The method of claim 5, further comprising:
forming a wire bundle by winding the substrate around an elongated core such that individual superconductor wires disposed within the channels of the substrate are rotationally and radially separated from each other and extend in a longitudinal direction of the elongated core.

10. The method of claim 9, further comprising:
drawing the wire bundle to elongate the wire bundle along a longitudinal axis of the wire bundle.

11. The method of claim 9, wherein the elongated core comprises an electrically conductive material.

12. The method of claim 11, wherein the elongated core comprises copper and the substrate comprises at least one of nickel, iron, a nickel alloy or an iron alloy.

13. The method of claim 5, further comprising:
separating the substrate into sections and along a line that extends between but does not traverse two channels so as to separate at least two superconductor wires into different sections.

14. The method of claim 1, wherein the substrate comprises at least one of copper, silver, gold, platinum, palladium, aluminum, iron, nickel, chromium magnesium, titanium, molybdenum, tungsten and lead.

15. The method of claim 14, further comprising:
prior to deposition of the material within the channel of the substrate, coating surface portions of the channel with a composition that is non-reactive with the material.

16. The method of claim 1, wherein the channel is non-linear.

17. The method of claim 5, wherein the plurality of channels and superconductor wires extend in substantially parallel relation along a longitudinal dimension of the substrate, the method further comprising:
forming a wire bundle by winding the substrate around an elongated core transversely of said longitudinal dimension such that individual superconductor wires disposed within the channels of the substrate are rotationally and radially separated from each other and extend in a longitudinal direction of the elongated core.

18. The method of claim 17, wherein at least one of the superconductor wires extends in a linear direction between opposing longitudinal ends of the elongated core.

19. The method of claim 17, wherein at least one of the superconductor wires extends in a non-linear direction between opposing longitudinal ends of the elongated core.

20. The method of claim 17, wherein at least one of the superconductor wires forms a helical shape around the elongated core.

21. The method of claim 5, further comprising:
forming an elongated wire bundle by rolling the substrate upon itself from a first edge of the substrate to a second edge of the substrate such that individual superconductor wires disposed within the channels of the substrate are rotationally and radially separated from each other and extend in a longitudinal direction of the elongated wire bundle.

22. A superconductor structure comprising:
a substrate including a channel formed within and along a surface of the substrate; and
an elongated superconductor wire disposed within the channel of the substrate, wherein the superconductor wire comprises a superconductor material formed as a single and cohesive structure within the channel.

23. The superconductor structure of claim 22, wherein the substrate comprises at least one of copper, silver, gold, platinum, palladium, aluminum, iron, nickel, chromium magnesium, titanium, molybdenum, tungsten and lead.

24. The superconductor structure of claim 23, wherein the channel is coated with a composition that is non-reactive with the superconductor material.

25. The superconductor structure of claim 22, wherein the superconductor material comprises magnesium diboride.

26. The superconductor structure of claim 22, wherein the substrate includes a plurality of channels formed within and along the surface of the substrate, and a plurality of elongated superconductor wires disposed within the channels of the substrate, each superconductor wire comprising a superconductor material formed as a single and cohesive structure within the channel.

27. The superconductor structure of claim 26, further comprising a second substrate secured to the surface of the substrate including the channels so as to enclose the superconductor wires within the channels between the substrates.

28. The superconductor structure of claim 27, wherein the second substrate includes a plurality of second channels formed within and along a surface of the second substrate and a plurality of elongated superconductor wires disposed within the second channels of the second substrate, each superconductor wire disposed within a corresponding second channel comprising a superconductor material formed as a single and cohesive structure within the second channel.

29. The superconductor structure of claim 22, wherein the channel is non-linear.

30. A superconductor cable comprising:
the superconductor structure of claim 26, wherein the substrate including the plurality of channels is rolled upon itself from a first edge of the substrate to a second edge of the substrate so as to form an elongated wire bundle in which individual superconductor wires disposed within the channels of the substrate are rotationally and radially separated from each other and extend in a longitudinal direction of the elongated wire bundle.

31. The superconductor cable of claim 30, further comprising:
an elongated core;
wherein the substrate of the superconductor structure is wound around the elongated core to form the elongated wire bundle.

32. The superconductor cable of claim 31, wherein the elongated core comprises an electrically conductive material.

33. The superconductor cable of claim 31, wherein the elongated core comprises copper and the substrate comprises at least one of nickel, iron, a nickel alloy or an iron alloy.

34. The superconductor cable of claim 30, wherein at least one of the superconductor wires extends in a linear direction between opposing longitudinal ends of the elongated wire bundle.

35. The superconductor cable of claim 30, wherein at least one of the superconductor wires extends in a non-linear direction between opposing longitudinal ends of the elongated wire bundle.

36. The superconductor cable of claim 31, wherein at least one of the superconductor wires forms a helical shape around the elongated core.
